(19) United States
(12) Patent Application Publication
(10) Pub. No.: US 2021/0242414 A1
(43) Pub. Date: Aug. 5, 2021

(54) METHOD FOR MANUFACTURING PRINTED ELECTRONIC DEVICE USING MULTI-PASSIVATION AND PRINTED ELECTRONIC DEVICE

(71) Applicant: RESEARCH & BUSINESS FOUNDATION SUNGKYUNKWAN UNIVERSITY, Suwon-si (KR)

(72) Inventors: Gyou jin CHO, Suwon-si (KR); Youn Su JUNG, Suwon-si (KR); Hye jin PARK, Suwon-si (KR); Jin Hwa PARK, Suwon-si (KR); KALE AMOL MAROTRAO, Suncheon-si (KR)

(73) Assignee: RESEARCH & BUSINESS FOUNDATION SUNGKYUNKWAN UNIVERSITY, Suwon-si (KR)

(21) Appl. No.: 17/149,775

(22) Filed: Jan. 15, 2021

(30) Foreign Application Priority Data
Jan. 30, 2020 (KR) 10-2020-0011228

(51) Int. Cl. H01L 51/05; H01L 51/00

(52) U.S. Cl. CPC H01L 51/0545; H01L 51/0004

(57) ABSTRACT

The present disclosure relates to a method for manufacturing a printed electronic device using multi-passivation and the printed electronic device. The method for manufacturing a printed electronic device using multi-passivation includes printing a printed electronic device including a gate electrode, a dielectric layer, a semiconductor layer, a source electrode and a drain electrode; and printing a multi-passivation layer of a multi-layer structure for passivating the printed electronic device by using amorphous fluoropolymer.

### CROSS-REFERENCE TO RELATED APPLICATIONS

This application claims priority to Korean Patent Application No. 10-2020-0011228 filed on Jan. 30, 2020 in Korea, the entire contents of which are hereby incorporated by reference in their entirety.

### BACKGROUND OF THE DISCLOSURE

### Field of the Disclosure

The present disclosure relates to a method for manufacturing a printed electronic device using multi-passivation and the printed electronic device.

### Related Art

Despite of various advantages (light weight, low price, flexibility, and large area) of the printed electronic technology, the technology is not spotlighted up to now since electronic devices using the technology have not been commercialized so far. The various printing techniques may be applied to manufactures of transistors, electronic circuits, sensors, memories and PCBs in various manners, however there are disadvantages in the aspects of low device lifetime and low yield in comparison with silicon (Si) based electronic devices. Particularly, since organic electronic devices are very vulnerable to humidity and oxygen, in the case of being exposed to air or in the case of an influx of external humidity, there is a disadvantage that the lifetime of the device is significantly reduced.

In order to solve the problem above, manufacturing methods are introduced such as an inorganic material is evaporated, external humidity or oxygen is sealed by introducing a metal cap, or the surface is passivated through a hardening process after coating the surface of an organic layer or a metal layer with a hardening film or a hardening material. The passivation process through a solution process has advantages in that the process makes a good strain-stress matching with an organic material based electronic device and the process and materials are environment-friendly, and the process is easy and simple to perform.

On the other hand, employing inorganic or metal layers as the passivation layer, there is difficulty in manufacturing it due to thermal coefficient difference from a substrate. Furthermore, the process of vacuum evaporation has low productivity, since multiple inorganic layers are evaporated, and it is difficulty in mass production with an ultra-low cost since all processes include vacuum and evaporation processes. In addition, even in the case of the passivation through vacuum evaporation and solution process, since a used material exerts direct influence on a printed semiconductor device, this alters on the electrical property of an electronic device. Some material makes an electronic device lose the property of organic semiconductor or makes it hard to drive a device.

The primary reason for those device variations after the passivation is originated from exposing to an external environment, humidity and oxygen are trapped in an interface between a semiconductor layer and a dielectric layer, and a parasitic trap charge is generated when a device bias is applied, and accordingly, a driving becomes unstable. Particularly, since N-type transistor is more vulnerable to humidity and oxygen (due to low LUMO (Lowest Unoccupied Molecular Orbital) level), it is hard to secure a device stability, and this is the biggest obstacle in implementing a printed flexible CMOS (Complementary metal-oxide-semiconductor) based device.

### SUMMARY

The embodiments of the present disclosure provides a method for manufacturing a printed electronic device using multi-passivation and the printed electronic device to improve the driving stability of a printed electronic device (printed transistor, etc.) using multi-passivation of a multiple structure having hydrophobic property.

However, the technical problem to solve of the present disclosure is not limited thereto and may be extended to the environment of the range which is not departing from the concept of the scope of the present disclosure in various manners.

In an aspect, a method for manufacturing a printed electronic device using multi-passivation may be provided. The method may include printing a printed electronic device including a gate electrode, a dielectric layer, a semiconductor layer, a source electrode and a drain electrode; and printing a multi-passivation layer of a multi-layer structure for passivating the printed electronic device by using amorphous fluoropolymer.

The step of printing the multi-passivation layer may include printing the multi-passivation layer of a multi-layer structure by using at least one material of CYTOP and FG-3650 having hydrophobic property, and surface modified aluminum oxide nano particle ink.

The step of printing the multi-passivation layer may include: forming a first passivation layer with CYTOP having hydrophobic property on the printed electronic device; forming a second passivation layer with FG-3650 having hydrophobic property or surface modified aluminum oxide nano particle ink on the first passivation layer; and forming a third passivation layer with CYTOP having hydrophobic property on the second passivation layer.

The step of printing the multi-passivation layer may include printing the multi-passivation layer through at least one printing process of a roll-to-roll gravure, a roll-to-roll reverse offset, a Flexographic Printing, an Inkjet Printing and a Spin Coating.

The step of printing the multi-passivation layer may include: forming a first multi-passivation layer of a multi-layer structure printed on an upper part of the printed electronic device; and forming a second multi-passivation layer of a multi-layer structure printed on a lower part of the printed electronic device.

The multi-passivation layer may form a barrier film of a multi-layer structure and encapsulate the printed electronic device.

The printed electronic device may be a p-type transistor or an n-type transistor, manufactured through a printing process.

The printed electronic device may be an organic material based printed transistor manufactured through a printing process.

Meanwhile, in another aspect, a printed electronic device using multi-passivation may be provided. The device may include a printed electronic device on which a gate electrode, a dielectric layer, a semiconductor layer, a source electrode and a drain electrode are printed; and a multi-passivation layer of a multi-layer structure printed for passivating the printed electronic device by using amorphous fluoropolymer.

The multi-passivation layer may be a multi-passivation layer of a multi-layer structure printed by using at least one material of CYTOP and FG-3650 having hydrophobic property, and surface modified aluminum oxide nano particle ink.

The multi-passivation layer may include: a first passivation layer formed with CYTOP having hydrophobic property on the printed electronic device; a second passivation layer formed with FG-3650 having hydrophobic property or surface modified aluminum oxide nano particle ink on the first passivation layer; and a third passivation layer formed with CYTOP having hydrophobic property on the second passivation layer.

The multi-passivation layer may be printed through at least one printing process of a roll-to-roll gravure, a roll-to-roll reverse offset, a Flexographic Printing, an Inkjet Printing and a Spin Coating.

The multi-passivation layer may include: a first multi-passivation layer of a multi-layer structure printed on an upper part of the printed electronic device; and a second multi-passivation layer of a multi-layer structure printed on a lower part of the printed electronic device.

The multi-passivation layer may form a barrier film of a multi-layer structure and encapsulate the printed electronic device.

The printed electronic device may be a p-type transistor or an n-type transistor, manufactured through a printing process.

The printed electronic device may be an organic material based printed transistor manufactured through a printing process.

The present disclosure may have the following technical effects. However, it is understood that a specific embodiment should include the whole effects below or only the effects, and therefore, the scope of the present disclosure is not limited thereto.

According to the embodiments of the present disclosure, the stability of a p-type or n-type printed transistor may be secured, which is manufactured through the roll-to-roll continuous process using a multi-passivation structure of a multi-layer structure, and the stability of a ring oscillator based on the transistor may be secured.

According to the embodiments of the present disclosure, a passivation material may be applied to various printing process such as the roll-to-roll gravure, the roll-to-roll reverse offset, the Flexographic Printing, the Inkjet Printing and the Spin Coating, and may also applied to various printed electronic devices in addition to a printed transistor.

According to the embodiments of the present disclosure, a multi-passivation material and structure of a multi-layer structure is used, and an organic material based transistor (monomer, polymer and oligomer) may be stably driven in an external environment (high temperature, low temperature and high humidity) for a long time while not exerting direct influences on the electrical property.

### BRIEF DESCRIPTION OF THE DRAWINGS

FIG. 1 is diagram illustrating a roll image of a printed CMOS type ring oscillator and the detailed p-type and n-type transistors.

FIGS. 2 and 3 are diagrams illustrating a general transfer curve of p-type and n-type transistors.

FIGS. 4 and 5 are configuration diagrams for describing a configuration of a printed electronic device using multi-passivation according to an embodiment of the present disclosure.

FIG. 6 is a flowchart illustrating a method for manufacturing a printed electronic device using multi-passivation according to an embodiment of the present disclosure.

FIGS. 7 to 9 are diagrams illustrating surface modified aluminum oxide nano particle ink of a passivation material according to an embodiment of the present disclosure.

FIGS. 10 and 11 are diagrams illustrating transfer curves of a printed transistor as time passes after introducing the passivation material according to an embodiment of the present disclosure.

FIGS. 12 to 15 are diagrams illustrating output frequencies and output voltages of a printing CMOS ring oscillator as time passes before and after introducing a multi-passivation layer according to an embodiment of the present disclosure.

FIGS. 16 to 18 are diagrams illustrating output voltages of an inverter depending on an external temperature and humidity after introducing a multi-passivation layer according to an embodiment of the present disclosure.

### DESCRIPTION OF EXEMPLARY EMBODIMENTS

Since the inventive concept may have diverse modified embodiments, preferred embodiments are illustrated in the drawings and described in the detailed description of the present disclosure. However, this does not limit the inventive concept within specific embodiments, and it is understood that the inventive concept covers all the modifications, equivalents, and replacements within the idea and technical scope of the inventive concept. Moreover, detailed descriptions related to well-known functions or configurations will be ruled out in order not to unnecessarily obscure subject matters of the inventive concept.

It will be understood that although the terms of first and second are used herein to describe various elements, these elements should not be limited by these terms. Terms are only used to distinguish one component from other components.

In the following description, the technical terms are used only for explaining a specific exemplary embodiment while not limiting the inventive concept. Terms used in the present disclosure have been selected as general terms which are widely used at present, in consideration of the functions of the inventive concept, but may be altered according to the intention of an operator of ordinary skill in the art, conventional practice, or introduction of new technology. Also, if there is a term which is arbitrarily selected by the applicant in a specific case, in which case a meaning of the term will be described in detail in a corresponding description portion of the present disclosure. Therefore, the terms should be defined on the basis of the entire content of this specification instead of a simple name of each of the terms.

The terms of a singular form may include plural forms unless referred to the contrary. The meaning of “comprise”, “include”, or “have” specifies a property, a region, a fixed number, a step, a process, an element and/or a component but does not exclude other properties, regions, fixed numbers, steps, processes, elements and/or components.

Hereinafter, exemplary embodiments will be described in detail with reference to the accompanying drawings. The same numbers refer to the same elements throughout the description of the figures, and a repetitive description on the same element is not provided.

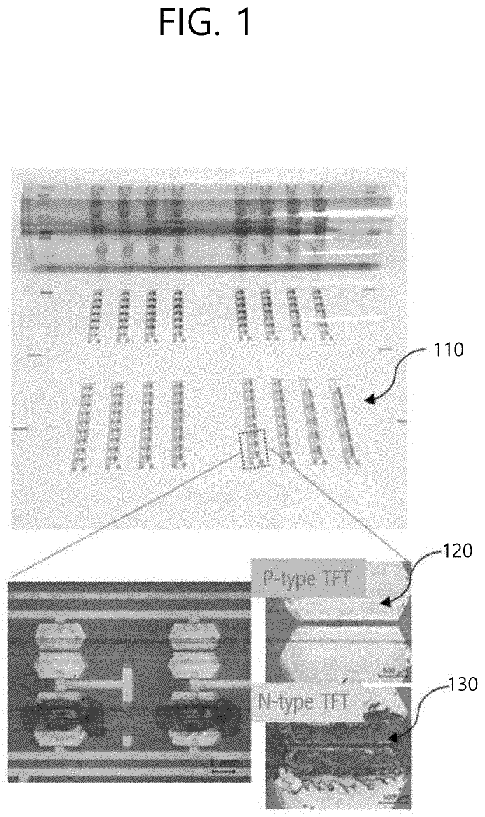

FIG. 1 is diagram illustrating a roll image of a printed CMOS type ring oscillator and the detailed p-type and n-type transistors.

FIG. 1 shows a roll image 110 of a CMOS type ring oscillator obtained through a roll-to-roll continuous printing process and the detailed p-type transistor 120 and n-type transistor 130.

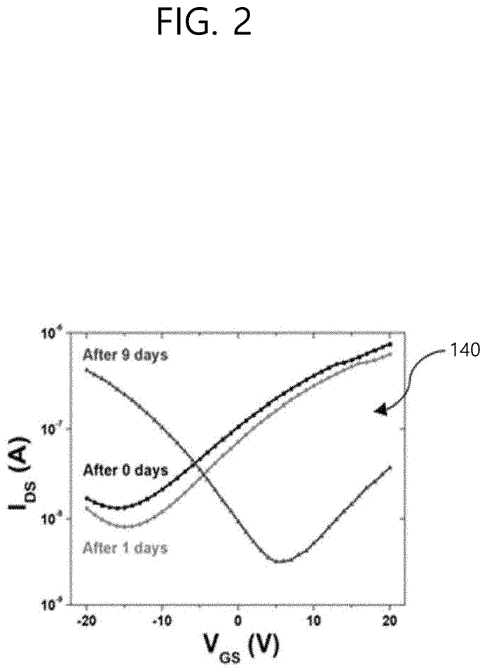

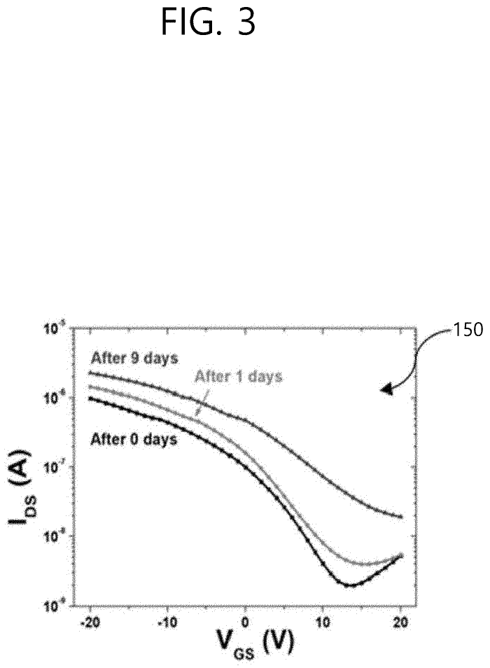

FIGS. 2 and 3 are diagrams illustrating a general transfer curve of p-type and n-type transistors.

FIG. 2 shows a transfer curve Vgs-Ids of an n-type transistor depending on a time in the state of not passivated. FIG. 3 shows a transfer curve Vgs-Ids of a p-type transistor depending on a time in the state of not passivated. That is, transfer curves of the transistors are shown depending on a time.

As shown in FIG. 2, an n-type transistor 140 produced through the roll-to-roll continuous printing process is vulnerable to an external environment and changed from n-type to p-type rapidly, particularly, by humidity and oxygen as time passes.

As shown in FIG. 3, even for a p-type transistor 150, a threshold voltage Vth or an on-current is changed as time passes.

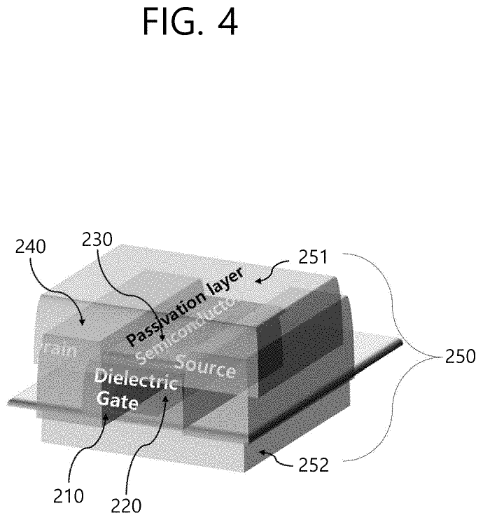

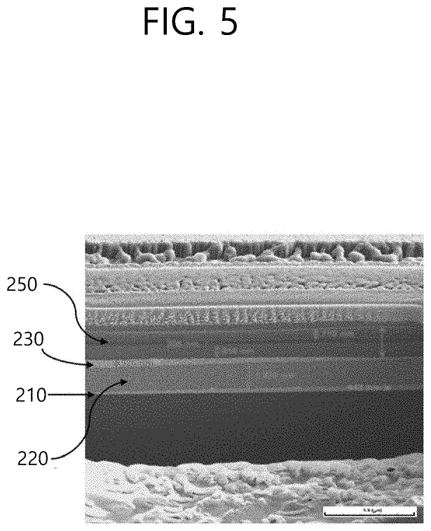

FIGS. 4 and 5 are configuration diagrams for describing a configuration of a printed electronic device using multi-passivation according to an embodiment of the present disclosure.

As shown in FIG. 4 and FIG. 5, a printed electronic device 200 passivated using multi-passivation according to an embodiment of the present disclosure includes a printed electronic device and a multi-passivation layer 250. However, not all the depicted elements are essential elements. The passivated printed electronic device 200 may be implemented with more elements than the depicted elements, and the passivated printed electronic device 200 may also be implemented with less elements than the depicted elements.

Hereinafter, detailed configuration and operation of each of the elements of the printed electronic device 200 shown in FIG. 4 and FIG. 5 are described.

In one example, in the case that the passivated printed electronic device 200 is a printed transistor, FIG. 4 shows an embodiment of the passivated printed electronic device, and FIG. 5 shows a section image of the passivated printed electronic device. The embodiments of the present disclosure may be a printed transistor or a printed electronic device which is passivated through a passivation process.

The electronic device includes a gate electrode 210, a dielectric layer 220, a semiconductor layer 230, a drain electrode and a source electrode 240. Here, the name of each element may be changed depending on a type of transistor. For example, the gate electrode 210, the drain electrode and the source electrode 240 may be referred to as a control electrode, a first current electrode and a second current electrode, respectively.

A multi-passivation layer 250 may have a multi-layer structure and passivate the electronic device by using amorphous fluoropolymer. In an embodiment of the present disclosure, the multi-passivation layer 250 may have a structure of multi-layers of CYTOP SP2, FG-3650 and CYTOP SP2, and the thickness may be 1 to 2 micrometers.

According to an embodiment, the multi-passivation layer 250 may be a multi-passivation layer of a multi-layer structure which is printed by using at least one material of CYTOP and FG-3650 having hydrophobic property, and surface modified aluminum oxide nano particle ink.

CYTOP is a material of Asahi Glass company of Japan, and the material may be used for a passivation coating material of several purposes since the material have high hydrophobic property.

FG-3650 is a material of Dulub company of Japan, and the material have hydrophobic property like CYTOP, and the product name is FG-3650 TH-8.0. The material is characterized that room temperature drying is possible, and complete drying is available for 5 to 30 seconds. In addition, FG-3650 is nonflammable and non-toxic, and accordingly, applicable for various manufacturing fields.

According to embodiments, the multi-passivation layer 250 may include a first passivation layer formed with CYTOP having hydrophobic property on the printed electronic device, a second passivation layer formed with FG-3650 having hydrophobic property or surface modified aluminum oxide nano particle ink on the first passivation layer, and a third passivation layer formed with CYTOP having hydrophobic property on the second passivation layer. As such, in an embodiment of the present disclosure, CYTOP or FG-3650 having hydrophobic property, or surface modified aluminum oxide nano particle ink is used, and external humidity and oxygen are blocked, and internal trap charges are fixed, and accordingly, a driving stability of a printed flexible CMOS electronic device may be secured.

According to embodiments, the multi-passivation layer 250 may be printed through at least one printing process of the roll-to-roll gravure, the roll-to-roll reverse offset, the Flexographic Printing, the Inkjet Printing and the Spin Coating.

According to embodiments, the multi-passivation layer 250 may include a first multi-passivation layer 251 of a multi-layer structure printed on an upper part of the printed electronic device and a second multi-passivation layer 252 of a multi-layer structure printed on a lower part of the printed electronic device.

According to embodiments, the multi-passivation layer 250 may form a barrier film of a multi-layer structure and encapsulate the printed electronic device. An embodiment of the present disclosure may form the barrier film of a multi-layer structure using a multi-passivation layer of a solution process and may provide a driving stability of a CMOS electronic device printed with n-type and p-type semiconductors.

According to embodiments, the printed electronic device 200 may be a p-type transistor or an n-type transistor, manufactured through the printing process.

According to embodiments, the printed electronic device 200 may be an organic material based printed transistor manufactured through the printing process.

As such, CYTOP SP2, which blocks external humidity and oxygen and does not influence on the electrical property of the printed transistor, is selected for the multi-passivation layer according to an embodiment of the present disclosure, and the multi-passivation layer may be printed on an upper part or a lower part of the printed transistor through the spin coating or the roll-to-roll printing process. In this way, in the step of manufacturing the passivation layer of a multi-layer structure by using CYTOP or FG-3650 having hydrophobic property, or surface modified aluminum oxide nano particle ink, particularly, the CYTOP layer that does not influence on the electrical property is introduced as the first passivation layer first as a method for providing stability of the printed transistor (or printed CMOS electronic device). And then, the second passivation layer is printed layer by using FG-3650 or surface modified aluminum oxide nano particle ink. Through this, the stability of the p-type transistor and the n-type transistor becomes possible.

When the passivation material is introduced on the printed transistor by using a material (PMMA (Poly methyl methacrylate), FG-3650, Dupont-AF, EPOXY, PDMS (Polydimethylsiloxane), etc.) in addition to CYTOP, on-current may be reduced (off-current is increased) or a threshold voltage may be significantly changed. That is, according to an embodiment of the present disclosure, a passivation material optimized for printed n-type and p-type transistors is used, and accordingly, a driving stability may be secured while not influencing on the material of the printed electronic device.

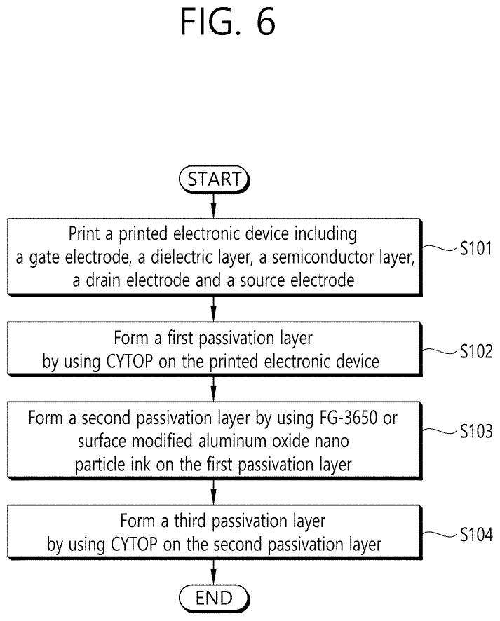

FIG. 6 is a flowchart illustrating a method for manufacturing a printed electronic device using multi-passivation according to an embodiment of the present disclosure.

In step S101, according to a method for manufacturing a printed electronic device, a printed electronic device is printed, which includes a gate electrode, a dielectric layer, a semiconductor layer, a drain electrode and a source electrode.

As in steps S102 to S104, according to the method for manufacturing a printed electronic device, a multi-passivation layer of a multi-layer structure is printed, which passivates the printed electronic device by using amorphous fluoropolymer.

In detail, in step S102, according to the method for manufacturing a printed electronic device, a first passivation layer is formed by using CYTOP having hydrophobic property on the printed electronic device.

In step S103, according to the method for manufacturing a printed electronic device, a second passivation layer is formed by using FG-3650 having hydrophobic property or surface modified aluminum oxide nano particle ink on the first passivation layer.

In step S104, according to the method for manufacturing a printed electronic device, a third passivation layer is formed by using CYTOP having hydrophobic property on the second passivation layer.

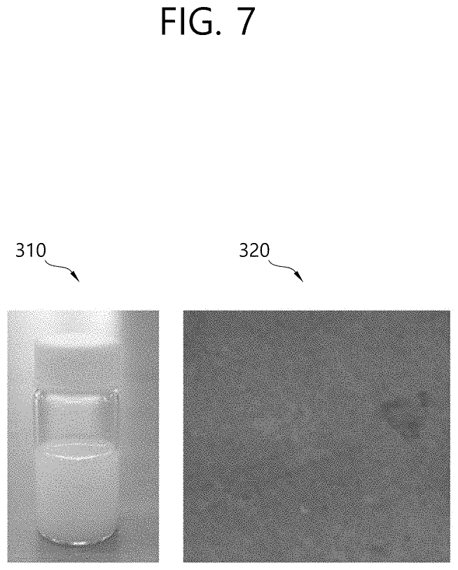

FIGS. 7 to 9 are diagrams illustrating surface modified aluminum oxide nano particle ink of a passivation material according to an embodiment of the present disclosure.

FIG. 7 to FIG. 9 show aluminum oxide nano particle ink and the surface image. FIG. 7 shows surface modified aluminum oxide nano particle based ink 310 as an example of a passivation material introduced on the multi-passivation layer according to an embodiment of the present disclosure.

According to an embodiment of the present disclosure, in order to manufacture the surface modified aluminum oxide nano particle based ink, 0.5 grams of aluminum oxide nano powder having a size of 10 to 15 nm and 1 gram of Stearic acid are added to 100 ml of Toluene, and mixed for 36 hours in 110° C., and accordingly, the surface modified aluminum oxide nano particle is manufactured.

Thereafter, distillation is performed by using a rotary evaporator, and drying of the solution is progressed for 12 hours in a vacuum oven of 70° C.

In addition, 12 grams of 2-propanol solution is added to 250 milligrams of the obtained aluminum oxide nano particle, and a dispersion process is progressed in a bath sonicator for about 40 minutes, and accordingly, used as ink. The dispersion of the manufactured ink may be identified by an optical image, and a micro-hole 320 is existed due to the nano particle size.

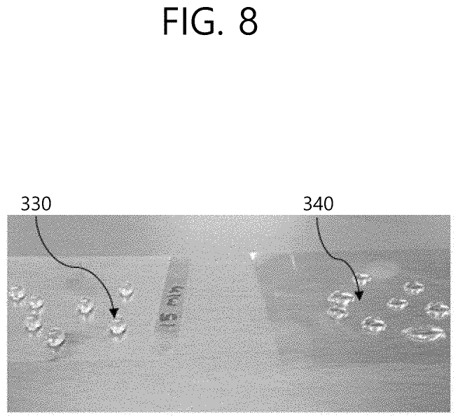

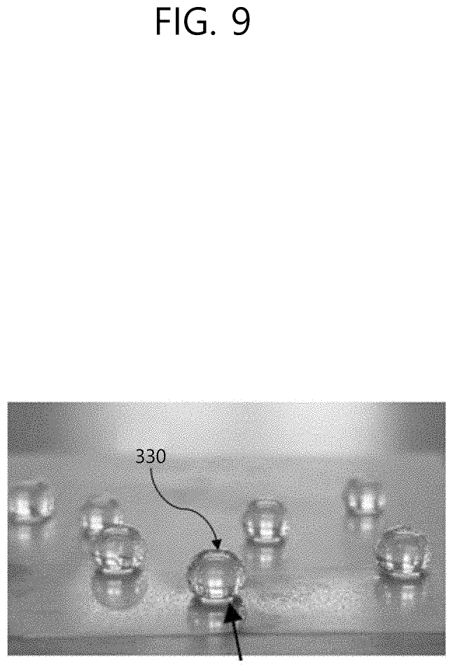

As shown in FIG. 8 and FIG. 9, owing to the hydrophobic property, a contact angle 340 with respect to water shows 140° or greater, which is greater than a contact angle 330 of 80° of the existing PET film.

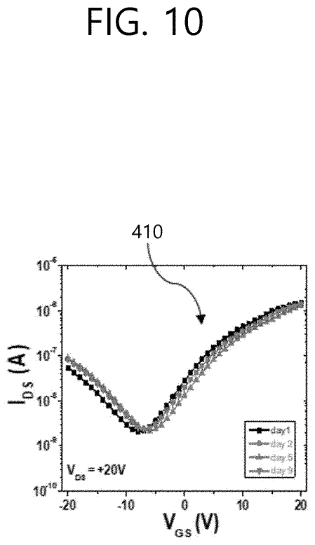

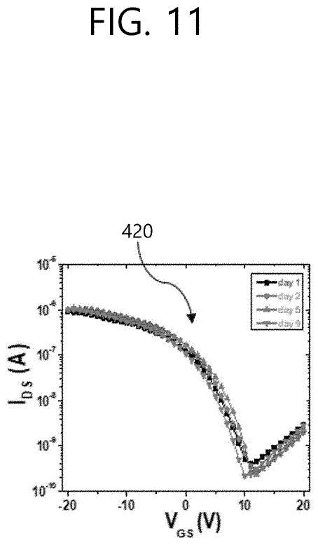

FIGS. 10 and 11 are diagrams illustrating transfer curves of a printed transistor as time passes after introducing the passivation material according to an embodiment of the present disclosure.

FIG. 10 and FIG. 11 show transfer curves of the transistor as time passes after introducing the passivation material.

In an embodiment of the present disclosure, for an n-type transistor 410 and a p-type transistor 420 to which a multi-passivation layer is introduced, even in the case that time passes (after 9 days), the electrical property (on-current, threshold voltage, mobility, etc.) is not changed. Particularly, the printed n-type transistor, which is vulnerable to external humidity, is stabilized after the passivation.

The multi-passivation layer introduced in an embodiment of the present disclosure may be applied to a printed electronic device through the spin coating or the roll-to-roll gravure printing equipment using CYTOP and FG-3650 or surface modified aluminum oxide nano particles. The process order is as described below. First, a first passivation layer is formed by introducing CYTOP SP2 that does not influence on the printed transistor. And then, a second passivation layer is formed by printing or introducing FG-3650 or surface modified aluminum oxide nano particles on the CYTOP SP2 layer to compensate. Later, a third passivation layer is formed by introducing CYTOP SP2 again, and the passivation effect is maximized. Alternatively, surface modified aluminum oxide nano particle ink may be introduced on the CYTOP SP2 layer.

The introduction of the multi-passivation layer is characterized that the spin coating method is performed in the rotational speed of 500 to 1000 rpm for 30 to 60 seconds, and then, the layer is dried for 5 to 10 minutes in a convention oven of 80° C. In the case that the multi-passivation layer is introduced by the roll-to-roll gravure, the printing speed is 5 to 8 m/min, and the layer is dried for 1 minute in a drying temperature of 80° C.

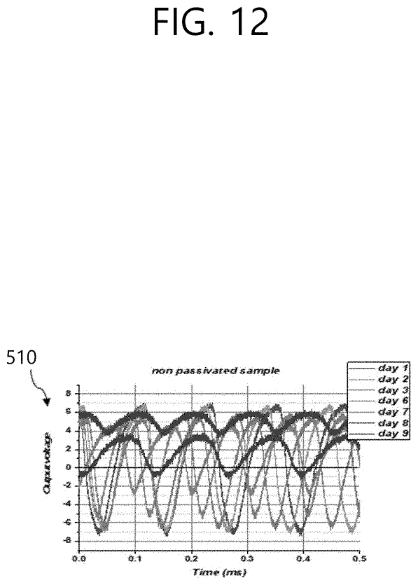

FIGS. 12 to 15 are diagrams illustrating output frequencies and output voltages of a printing CMOS ring oscillator as time passes before and after introducing a multi-passivation layer according to an embodiment of the present disclosure.

FIG. 12 to FIG. 15 show the output frequencies and the peak-to-peak voltages of the CMOS type printing ring oscillator as time passes before and after introducing the multi-passivation layer.

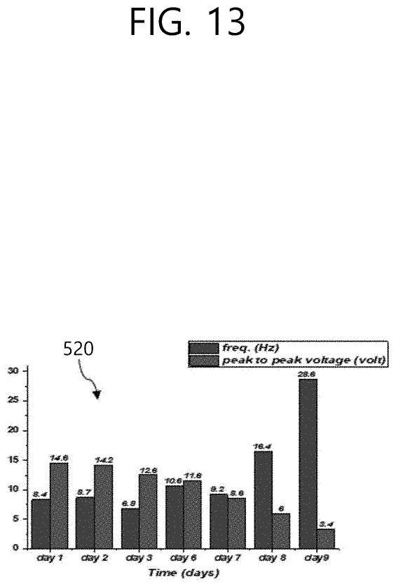

As shown in FIG. 12 and FIG. 13, the case of a ring oscillator sample 510 to which the multi-passivation layer is not introduced has the general characteristics 520 that the output voltage is continuously decreased as time passes, and the frequency is increased.

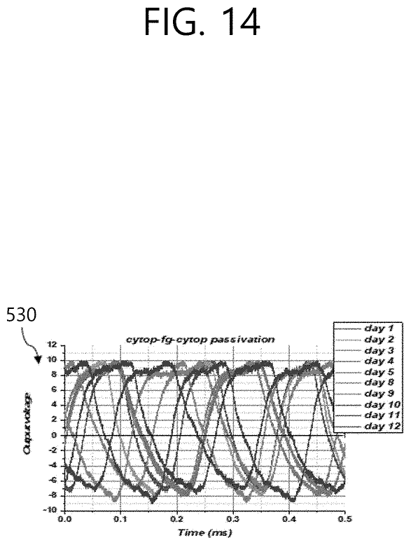

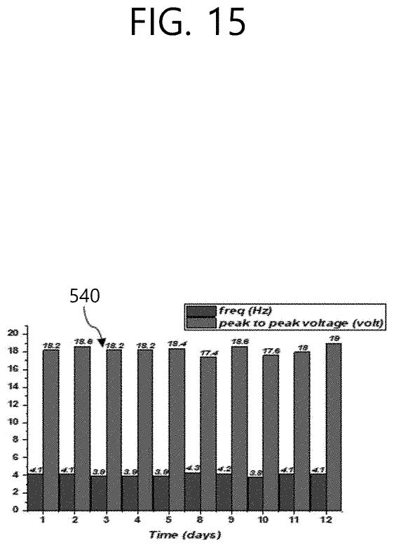

On the other hand, as shown in FIG. 14 and FIG. 15, the case of introducing the multi-passivation layer has the characteristics 540 that the output voltage and frequency of the ring oscillator 530 become uniform. The multi-passivation layer of a multi-layer structure according to an embodiment of the present disclosure is applicable to a non-uniform surface of a thickness of 2 micrometers or greater, different from that of a single-layer structure.

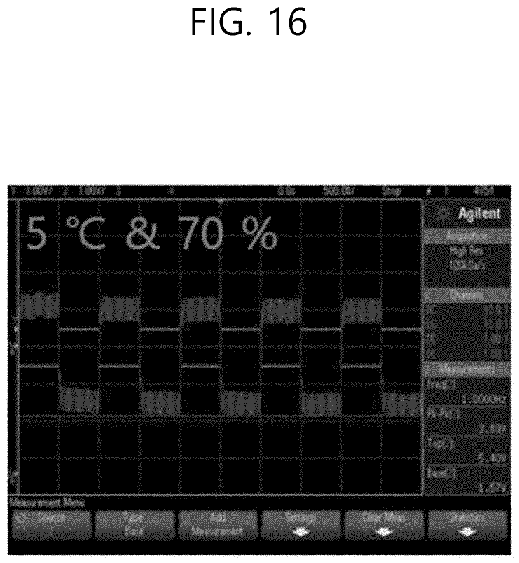

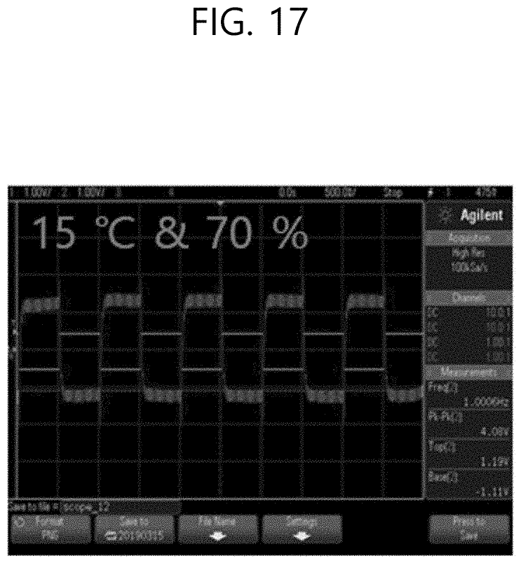

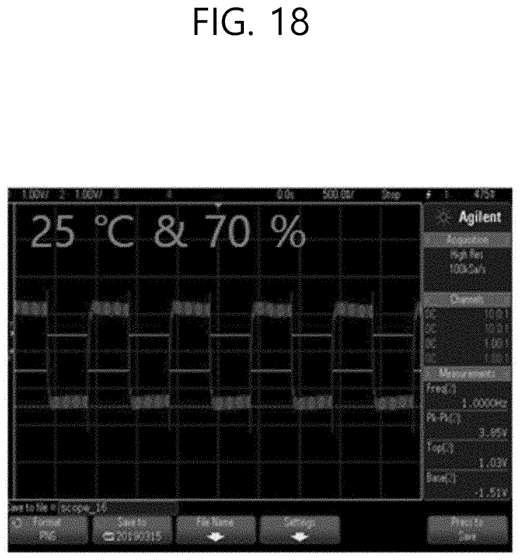

FIGS. 16 to 18 are diagrams illustrating output voltages of an inverter depending on an external temperature and humidity after introducing a multi-passivation layer according to an embodiment of the present disclosure.

FIG. 16 to FIG. 18 show output voltage graphs of a multi-passivated printed inverter depending on an external temperature and humidity.

FIG. 16 to FIG. 18 show output voltage graphs of the inverter depending on an external temperature and humidity after introducing a multi-passivation layer. The output voltage of the inverter is stabilized depending on temperature and humidity. The printed inverter in which the multi-passivation layer is formed is characterized that the property of the inverter is not degraded even in a low temperature of 5° C., and the inverter is stably driven even at a high humidity of 70%.

As described above, according to an embodiment of the present disclosure, a passivation structure of a multi-layer structure is formed by using CYTOP and FG-3650 having hydrophobic property, and surface modified aluminum oxide nano particles, and the stability of a printed transistor (e.g., printed CMOS electronic device) may be improved.

According to an embodiment of the present disclosure, a multi-passivation structure of a multi-layer structure may secure the stability of a p-type or n-type printed transistor manufactured through the roll-to-roll continuous process and may secure the stability of a ring oscillator based on the transistor.

According to an embodiment of the present disclosure, when a multi-passivation layer is introduced to a CMOS type ring oscillator configured with p-type and n-type, and the CMOS type ring oscillator is driven, the driving stability (e.g., high humidity and temperature, etc.) may be secured.

According to an embodiment of the present disclosure, by using a multi-passivation structure of a multi-layer structure, the stability of an n-type transistor which is vulnerable to external humidity and oxygen may be secured.

According to an embodiment of the present disclosure, a passivation material may be applied to various printing process such as the roll-to-roll gravure, the roll-to-roll reverse offset, the Flexographic Printing, the Inkjet Printing and the Spin Coating, and may also applied to various printed electronic devices in addition to a printed transistor.

According to an embodiment of the present disclosure, a multi-passivation material and structure enables an organic material based transistor (monomer, polymer and oligomer) to be stably driven in an external environment (high temperature and high humidity) for a long time while not exerting direct influences on the electrical property.

So far, the preferred embodiment of the inventive concept has been depicted and described, but the inventive concept is not limited to the specific embodiment described above, and it is understood that various modifications can be made by an ordinary skilled person in the art without departing from the concept of the present disclosure claimed in the claims, and the modifications should not be individually understood from the inventive concept or prospect of the present disclosure.

What is claimed is:

1. A method for manufacturing a printed electronic device using multi-passivation, the method comprising:
printing a printed electronic device including a gate electrode, a dielectric layer, a semiconductor layer, a source electrode and a drain electrode; and
printing a multi-passivation layer of a multi-layer structure for passivating the printed electronic device by using amorphous fluoropolymer.

2. The method for manufacturing a printed electronic device using multi-passivation of claim 1, wherein the step of printing the multi-passivation layer includes printing the multi-passivation layer of a multi-layer structure by using at least one material of CYTOP and FG-3650 having hydrophobic property, and surface modified aluminum oxide nano particle ink.

3. The method for manufacturing a printed electronic device using multi-passivation of claim 1, wherein the step of printing the multi-passivation layer includes:
forming a first passivation layer with CYTOP having hydrophobic property on the printed electronic device;
forming a second passivation layer with FG-3650 having hydrophobic property or surface modified aluminum oxide nano particle ink on the first passivation layer; and
forming a third passivation layer with CYTOP having hydrophobic property on the second passivation layer.

4. The method for manufacturing a printed electronic device using multi-passivation of claim 1, wherein the step of printing the multi-passivation layer includes printing the multi-passivation layer through at least one printing process of a roll-to-roll gravure, a roll-to-roll reverse offset, a Flexographic Printing, an Inkjet Printing and a Spin Coating.

5. The method for manufacturing a printed electronic device using multi-passivation of claim 1, wherein the step of printing the multi-passivation layer includes:
forming a first multi-passivation layer of a multi-layer structure printed on an upper part of the printed electronic device; and
forming a second multi-passivation layer of a multi-layer structure printed on a lower part of the printed electronic device.

6. The method for manufacturing a printed electronic device using multi-passivation of claim 1, wherein the multi-passivation layer forms a barrier film of a multi-layer structure and encapsulates the printed electronic device.

7. The method for manufacturing a printed electronic device using multi-passivation of claim 1, wherein the printed electronic device is a p-type transistor or an n-type transistor, manufactured through a printing process.

8. The method for manufacturing a printed electronic device using multi-passivation of claim 1, wherein the printed electronic device is an organic material based printed transistor manufactured through a printing process.

9. A printed electronic device using multi-passivation, the device comprising:
a printed electronic device on which a gate electrode, a dielectric layer, a semiconductor layer, a source electrode and a drain electrode are printed; and
a multi-passivation layer of a multi-layer structure printed for passivating the printed electronic device by using amorphous fluoropolymer.

10. The printed electronic device using multi-passivation of claim 9, wherein the multi-passivation layer is a multi-passivation layer of a multi-layer structure printed by using at least one material of CYTOP and FG-3650 having hydrophobic property, and surface modified aluminum oxide nano particle ink.

11. The printed electronic device using multi-passivation of claim 9, wherein the multi-passivation layer includes:
a first passivation layer formed with CYTOP having hydrophobic property on the printed electronic device;
a second passivation layer formed with FG-3650 having hydrophobic property or surface modified aluminum oxide nano particle ink on the first passivation layer; and
a third passivation layer formed with CYTOP having hydrophobic property on the second passivation layer.

12. The printed electronic device using multi-passivation of claim 9, wherein the multi-passivation layer is printed through at least one printing process of a roll-to-roll gravure, a roll-to-roll reverse offset, a Flexographic Printing, an Inkjet Printing and a Spin Coating.

13. The printed electronic device using multi-passivation of claim 9, wherein the multi-passivation layer includes:
a first multi-passivation layer of a multi-layer structure printed on an upper part of the printed electronic device; and
a second multi-passivation layer of a multi-layer structure printed on a lower part of the printed electronic device.

14. The printed electronic device using multi-passivation of claim 9, wherein the multi-passivation layer forms a barrier film of a multi-layer structure and encapsulates the printed electronic device.

15. The printed electronic device using multi-passivation of claim 9, wherein the printed electronic device is a p-type transistor or an n-type transistor, manufactured through a printing process.

16. The printed electronic device using multi-passivation of claim 9, wherein the printed electronic device is an organic material based printed transistor manufactured through a printing process.
